(19) United States
(12) Patent Application Publication
(10) Pub. No.: US 2011/0308602 A1
(43) Pub. Date: Dec. 22, 2011

(54) SOLAR CELL, SOLAR CELL MANUFACTURING METHOD AND TESTING METHOD

(75) Inventors: Matthias JUNGHÄNEL, Leipzig (DE); Andreas KUX, Haar (DE); Martin SCHÄDEL, Halle (Saale) (DE); Maximilian SCHERFF, Dortmund (DE)

(73) Assignee: Q-CELLS SE, Bitterfeld-Wolfen / OT Thalheim (DE)

(21) Appl. No.: 13/161,977

(22) Filed: Jun. 16, 2011

(30) Foreign Application Priority Data
Jun. 18, 2010 (DE) 102010017461.0-33

(51) Int. Cl. H01L 31/0224; H01L 31/18; G01R 31/26; H01L 31/0232

(52) U.S. Cl. 136/256; 136/259; 438/72; 324/761.01; 257/E31.12

(57) ABSTRACT

A solar cell includes a semiconductor substrate and an antireflection layer arranged on the light incidence side on the front-side surface of a semiconductor substrate. The antireflection layer has a limit voltage of less than 10 volts, less than 5 volts, or less than 3 volts, along a layer thickness of the antireflection layer.

### CROSS-REFERENCE TO RELATED APPLICATIONS

This application claims priority from German patent application No. 102010017461.0-33 filed on Jun. 18, 2010, the entire disclosure of which is incorporated herein by reference.

### DESCRIPTION

The invention relates to a solar cell, a solar cell manufacturing method, and a test method.

The most efficient solar modules at the present time are composed of individual solar cells interconnected to form strings by means of so-called cell connectors. For protection against environmental influences, said strings are coated with a plastic film and incorporated into a frame in a manner covered by a glass plate. In addition, the solar module is encapsulated along the solar cell rear sides by means of a rear-side film. Therefore, incident light passes firstly through the glass plate, subsequently through the plastic film, and then impinges on the front side of a solar cell. The plastic film is usually formed from ethylene vinyl acetate (EVA). In addition, in order to reduce the back-reflection of the incident light, the solar cells are generally coated with an antireflection layer, such that the layer surface of the antireflection layer bears against the plastic film.

During the operation of the solar module in a string composed of one or a plurality of solar modules, a potential arises between the solar cells and the frame. In the case of a series interconnection of the solar cells in the solar module, the electrical potential between the solar cells and the frame rises along the series. An industrially conventional limit for said potential is approximately 1000 volts, which are permitted to be present along a series interconnection and for which the rear-side film is generally also designed. If, in this case, a solar cell has a negative or positive potential relative to the frame, positive ions, for example sodium, calcium or magnesium ions, or negative ions, for example hydroxide ions (OH—), can correspondingly migrate within the glass plate and out of the glass plate and within the plastic film along the electric field present in the direction towards the solar cell. This brings about a charge carrier accumulation at the interface between glass plate and plastic film and/or at the interface between plastic film and antireflection layer, which can lead to a disturbance of the solar cell function. Inter alia, the parallel resistance can thereby be reduced, which can in turn bring about a partial or even complete failure of the affected solar cell. This degradation effect based on an induced potential difference between module frame and solar cell is designated as potential-induced degradation (PiD).

One possible procedure for protecting the solar cells against such a failure consists in avoiding negative potential differences (in the case of a front-side n-type emitter) and positive potential differences (in the case of a front-side p-type emitter) between the frame of the solar module and the solar cells contained therein. However, the earthing measures required for this purpose can be very complex, under certain circumstances. In addition, the selection of the current inverters is thereby restricted and the system efficiency can be adversely influenced. Furthermore, the use of glass plates composed of borosilicate glass is possible, because they contain fewer ionic constituents which can contribute to the accumulation of charges. However, the resultant increase in costs for the solar modules would not be economically acceptable. Finally, it can be attempted to produce the plastic film from a more suitable material than EVA, for example from silicones (for example Tectosil from Wacker), PVB (polyvinyl butyral) or thermoplastic (for example Surlyn from Dupont), since EVA is suspected of negative influences owing to the included acetic acid and high water and moisture permeability. It is found, however, that EVA films are very advantageous for use in solar modules for various reasons.

Therefore, it is an object of the invention to reduce or even substantially completely preclude the risk of a potential-induced degradation in solar cells in an effective and cost-effective manner.

The object is achieved according to the invention by means of a solar cell comprising the features of claim 1, a solar cell manufacturing method comprising the features of claim 11, and a test method comprising the features of claim 12. Advantageous developments of the invention are presented in the dependent claims.

The invention is based on the concepts that, in the solar cell incorporated in the solar module, the accumulation of charges at the interfaces of glass plate/plastic film and/or plastic film/antireflection layer is responsible for the potential-induced degradation. Therefore, the consideration underlying the invention is that the solar cell has to be embodied in such a way that said charges, through the antireflection layer, that is to say along the layer thickness of the antireflection layer or transversely with respect to a layer surface of the antireflection layer, flow away to the semiconductor substrate or are neutralized. The limit voltage can be regarded as the voltage, from which on an equilibrium of the current flowing to the interface of plastic film/antireflection layer and the current flowing away through or along the antireflection layer is established. Only then is further accumulation of charges at the interface no longer possible.

The inventors have discovered that the potential-induced degradation in the finished assembled solar module is effectively prevented whenever the antireflection layer of each of the individual solar cells itself has a limit voltage lying below a specific value. For the measurement of the limit voltage of the antireflection layer, in the case of the solar cell that has not been contact-connected, that is to say during solar cell production after the deposition of the antireflection layer but before metallization, a corona discharge is produced on the antireflection layer. In this case, the semiconductor substrate on which the antireflection layer is arranged serves as one electrode and a corona discharge electrode serves as a further electrode for the corona discharge. An electrical surface voltage on the layer surface of the antireflection layer is subsequently measured.

Said electrical surface voltage can vary along the layer surface of the antireflection layer and can be measured by means of a capacitive probe, for example by means of a Kelvin probe. If the measured electrical surface voltage is less than a limit voltage having a value presented previously, it can be assumed that the solar cell with this antireflection layer in the solar module experiences no potential-induced degradation even without earthing.

The corona discharge produces a surface charge on the layer surface of the antireflection layer by virtue of the fact that a high voltage of a few kilovolts (kV) is applied between a rear-side surface of the semiconductor substrate, which can be a semiconductor wafer, for example, and the corona discharge electrode. In this case, the corona discharge electrode is arranged at a distance of a few centimetres (cm) above the layer surface of the antireflection layer. The measurement of the electrical surface voltage is carried out immediately afterwards. As an example, the applied high voltage can be 5.2 kV, the distance between the layer surface of the antireflection layer and the tip of the corona discharge electrode being approximately 10 cm. In this case, a current flow in the corona of approximately 0.2 microampere (μA) is established, which, after approximately 30 minutes, causes no further change in the electrical surface voltage that can subsequently be measured by means of a Kelvin probe, for example.

The electrical surface voltage measured on the layer surface of the antireflection layer can preferably be the breakdown voltage of the antireflection layer. In this case, the limit voltage describes a maximum breakdown voltage which is permitted to be present in order that the solar cell can be classified as non-susceptible to potential-induced degradation. However, the limit voltage is a more general parameter than the breakdown voltage. A breakdown voltage can be used only to characterize antireflection layers which follow a breakdown characteristic curve. In this case, when the breakdown voltage is exceeded, the current through the layer rises exponentially. By contrast, the limit voltage can also be used to characterize an antireflection layer which has a conductivity even at low voltage, but the conductivity of which is sufficient to allow charge to be transported away effectively only upon the limit voltage being exceeded. Consequently, with the treatments of the antireflection layer for reducing the limit voltage, as described below, it is possible to increase the conductivity of the antireflection layer and/or to reduce its breakdown voltage.

During the production of the solar cell described here, the production parameters should be chosen in such a way that the antireflection layer, as explained, has a sufficiently low limit voltage. Alternatively or additionally, the test method described above can also be used to test the limit voltage of the antireflection layer and to classify those solar cells which satisfy the above criterion as suitable for further processing to form solar modules. By comparison with the otherwise conventional procedure, in which the susceptibility to potential-induced degradation (PiD) can be identified only after the solar cell has been incorporated into the solar module, the test method described here has the advantage that said PiD susceptibility can still occur before the solar cell is incorporated into the solar module. Solar cells classified as susceptible to PiD can then already be separated out at an early stage.

There are a series of procedures for producing an antireflection layer with the desired limit voltage. This is preferably done by means of the selection of the material of the antireflection layer and/or the stoichiometric composition of the substance compound from which the antireflection layer is formed.

In specific embodiments it is possible to set the limit voltage of the antireflection layer by means of a suitable choice of the refractive index value thereof, because the limit voltage can be dependent on the refractive index given otherwise identical parameters. On the other hand, it is particularly advantageous if the limit voltage lies below the values described above, although the refractive index is low. Specifically, one preferred embodiment provides for the antireflection layer to have a refractive index, determined at a wavelength of 632 nm, of less than n=2.2, n=2.15, n=2.1, n=2.05, n=2.0, n=1.9, n=1.8, n=1.6 or n=1.4. PiD occurs particularly frequently in the case of such low refractive index values. By means of the selection of a suitably low limit voltage, however, the occurrence of PiD can be precluded in this case, too. The optical properties of the antireflection layer, in particular the refractive index, can thus be separated from the electrical properties, namely the limit voltage. This ensures that the antireflection layer can still comply with its actual function in the solar cell.

One advantageous development provides for the antireflection layer to be doped. A doping of the antireflection layer with suitable dopants affords a possibility for reducing the limit voltage of the antireflection layer by virtue of the conductivity of the antireflection layer being increased. One expedient configuration provides for the antireflection layer to be doped with phosphorus, arsenic, fluorine or boron. Alternatively, other suitable substances or a substance compound can also be used as dopants.

In accordance with one preferred embodiment, a transparent conductive oxide is admixed in the antireflection layer. As such a transparent conductive oxide, by way of example, indium tin oxide, aluminium zinc oxide, antimony tin oxide or fluorine tin oxide is suitable for use within the antireflection layer.

In one advantageous embodiment, the concentration of defects in the antireflection layer is set in order to influence the conductivity of the antireflection layer in a targeted manner. In other words, during the production of this embodiment, the conductivity of the antireflection coating has been influenced in a targeted manner by way of the concentration of defects in the antireflection coating. Such defects can be, for example: an increased number of dangling bonds, produced by, for example, a reduced proportion of hydrogen in the layer.

It is preferably provided that the antireflection layer has conductivity channels running along the layer thickness or along a layer surface of the antireflection layer. Said channels can be formed, for example, by means of laser removal in the antireflection layer. The conductivity channels can be filled with a conductivity-increasing material. Alternatively, the conductivity channels can remain empty, the increase in conductivity taking place on account of surface conduction along inner surfaces of the conductivity channels.

Conductivity channels along the layer surface of the antireflection layer are preferably shallow trenches or planar covering layers which are formed in the layer surface. By contrast, the conductivity channels running along the layer thickness are preferably holes in the antireflection layer. One expedient embodiment provides for the conductivity channels in the antireflection layer to extend through the entire layer thickness of the antireflection layer. This therefore involves through-holes through the antireflection layer which extend as far as the underlying semiconductor substrate.

One advantageous configuration provides for the antireflection layer to be formed from silicon carbide, silicon oxide, silicon nitride, silicon oxynitride, aluminium oxide, metal oxide or a combination thereof. The antireflection layer can also be constructed from a plurality of partial layers. In this case, the individual partial layers can each be formed from a different material, preferably comprising one of the silicon compounds presented above.

One preferred development provides for contact electrodes to be arranged on the antireflection layer. This embodiment therefore involves a solar cell contact-connected on both sides, in which a contact-connection is present both on the front side and on the rear side. Preferably, however, all embodiments described herein can also be used in connection with solar cells which are exclusively contact-connected on the rear side, and in which, therefore, the contact electrodes for both polarizations are arranged on the solar cell rear side.

### BRIEF DESCRIPTION OF THE DRAWINGS:

The invention is explained below on the basis of exemplary embodiments with reference to the figures, in which:

FIGS. 1a-1e show schematic cross-sectional views of intermediate steps in the production of a solar cell in accordance with a preferred embodiment;

FIG. 2 shows a solar cell with a doped antireflection layer;

FIG. 3 shows a solar cell with an antireflection layer provided with conductivity channels;

FIG. 4 schematically shows a measurement set-up for testing the susceptibility of a solar cell to potential-induced degradation; and

FIG. 5 shows a schematic cross section through a solar cell incorporated into a solar module.

### DETAILED DESCRIPTION OF THE DRAWINGS

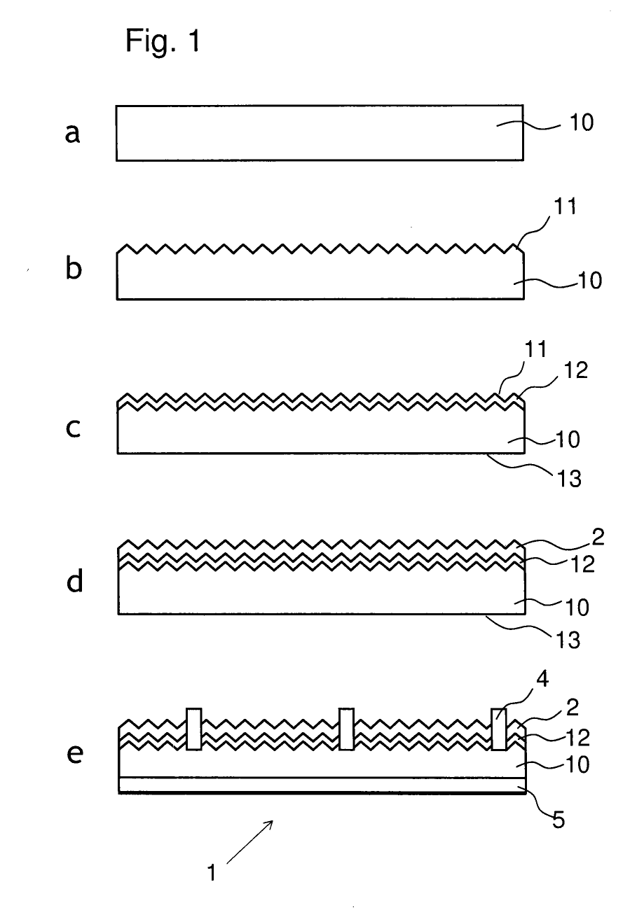

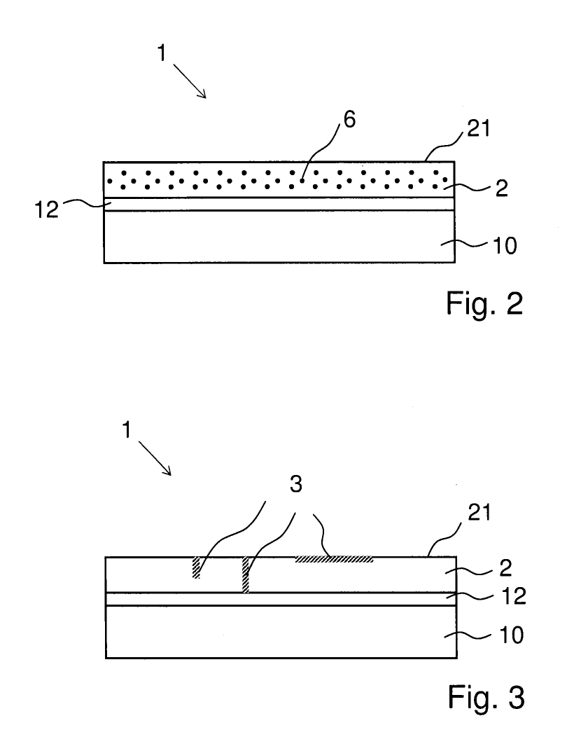

FIGS. 1a to 1e illustrate a solar cell manufacturing method. In this case, firstly in accordance with FIG. 1a a semiconductor substrate 10 is provided, preferably in the form of a silicon wafer. After possible cleaning steps, the semiconductor substrate 10 is subjected to a surface texture method in order to texture a front-side surface 11. The resulting surface texture is illustrated schematically in FIG. 1b and serves to lengthen the absorption path of the incident light in the semiconductor crystal. Even though the texture is not illustrated schematically in FIGS. 2 and 3 in connection with subsequently explained embodiments of the solar cell, it can preferably be present there as well.

As illustrated in FIG. 1c, after the texture step in the semiconductor substrate 10, by means of doping, an emitter doping layer 12 is formed on the front-side surface 11 in order to form a pn junction. Afterwards, an antireflection layer 2 is applied to the emitter doping layer 12 in order to obtain the structure illustrated in FIG. 1d. Finally, the solar cell 1 is metallized on both sides, wherein contact electrodes 4 are applied on the front-side surface 11, said contact electrodes penetrating through the antireflection layer 2 and being electrically connected to the emitter doping layer 12. On the rear-side surface 13, by contrast, a whole-area rear-side metallization 5 is applied, preferably by means of the application of a metal paste and a subsequent thermal treatment. Even though the solar cell 1 is contact-connected on both sides in the embodiment illustrated in FIG. 1e, all features explained above and below concerning the antireflection layer 2 can also be applied to solar cells 1 that are exclusively contact-connected on the rear side.

The antireflection layer 2 produced on the solar cell during the manufacturing method in accordance with FIGS. 1a to 1e has a limit voltage of less than 10 volts, less than 5 volts, or less than 3 volts. Two examples of how this is realized are illustrated in FIGS. 2 and 3.

The solar cell in accordance with FIG. 2 has an antireflection layer 2 that is doped. The resultant doping centres 6 are depicted schematically as dots in FIG. 2. Through a suitable choice of dopant, it is possible to increase the conductivity of the antireflection layer 2 perpendicularly to the layer surface 21 thereof, in order to reduce the limit voltage to a desired value.

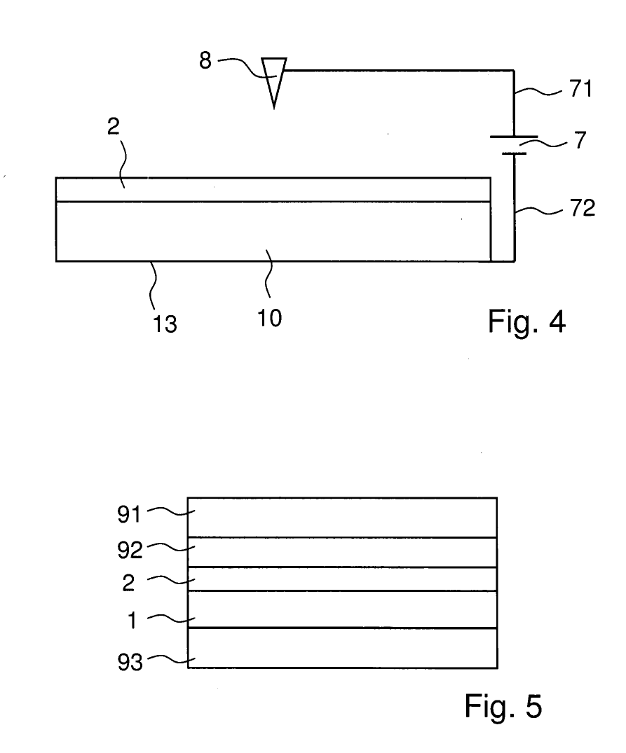

The test method for testing a solar cell 1 for its susceptibility to potential-induced degradation in a solar module can be carried out by means of the arrangement illustrated in FIG. 4. The arrangement comprises a high-voltage source 7, the positive voltage pole 71 of which is connected to a corona discharge electrode 8, and the negative voltage pole 72 of which is connected to the rear-side surface 13 of the semiconductor substrate 10. By way of example, the semiconductor substrate 10 can bear on a metal plate that is contact-connected to the negative voltage pole 72.

The corona discharge electrode 8 is arranged at a distance of a few centimetres above the front-side surface 11 of the semiconductor substrate 10. By applying a high voltage between corona discharge electrode 8 and solar cell 1, a corona is produced on the layer surface 21 of the antireflection layer 2, with a very low current in the microamperes range. Then, after a certain time, for example after a few or approximately 30 minutes, it is possible to measure the electrical surface voltage on the layer surface 21 of the antireflection layer 2. This is preferably effected by means of a Kelvin probe, which, however, is not illustrated in FIG. 4. For this purpose, the Kelvin probe is caused to oscillate and guided close to the layer surface 21.

FIG. 5 schematically illustrates a cross section through a solar cell incorporated in a solar module. This is merely intended to illustrate the arrangement of the different layers that are relevant to the potential-induced degradation with respect to one another. Therefore, by way of example, the rear-side metallization of the solar cell 1 is not depicted as a separate layer. In the solar module, the solar cell 1 with the antireflection layer 2 is protected from environmental influences by a plastic film 92 and a glass plate 91 on the front side and by a rear-side encapsulation 93 on the rear side. The rear-side encapsulation 93 is preferably a rear-side film.

If, in a conventional solar module as an example with a positive front-side emitter, the solar cell 1 has a negative potential relative to the frame of the solar module, positive ions situated in the glass plate 91 migrate through the glass plate 91 and, if appropriate, through the plastic film 92 and can accumulate at the interfaces between the glass plate 91 and the plastic film 92 and/or between the plastic film 92 and the semiconductor substrate 10 of the solar cell 1. Embodying the antireflection layer 2 as described above ensures that, before the accumulation of a relatively large quantity of charge at said interfaces, the charge can flow away through the antireflection layer 2 into the semiconductor substrate 10 of the solar cell 1.

1. A Solar cell comprising a semiconductor substrate and an antireflection layer arranged on the light incidence side on the front-side surface of the semiconductor substrate, said antireflection layer having a limit voltage of less than 10 volts, across a layer thickness of the antireflection layer.

2. The solar cell according to claim 1, wherein the antireflection layer has a refractive index, determined at a light wavelength of 632 nm, of less than n=2.2.

3. The solar cell according to claim 1, wherein the antireflection layer is doped.

4. The solar cell according to claim 3, wherein the antireflection layer is doped with phosphorus, arsenic, fluorine or boron.

5. The solar cell according to claim 1, wherein a transparent conductive oxide is admixed in the antireflection layer.

6. The solar cell according to claim 1, wherein the concentration of defects in the antireflection layer is set in order to influence the conductivity of the antireflection layer in a targeted manner.

7. The solar cell according to claim 1, wherein the antireflection layer has conductivity channels running across the layer thickness or along a layer surface of the antireflection layer.

8. The solar cell according to claim 5, wherein the conductivity channels in the antireflection layer extend through the entire layer thickness of the antireflection layer.

9. The solar cell according to claim 1, wherein the antireflection layer is formed from silicon carbide, silicon oxide, silicon nitride, silicon oxynitride, aluminium oxide, metal oxide or a combination thereof.

10. The solar cell according to claim 1, wherein the contact electrodes are arranged on the antireflection layer.

11. A Solar cell manufacturing method comprising the following method steps:
providing a semiconductor substrate; and
applying an antireflection layer to a front-side surface of the semiconductor substrate on the light incidence side in such a way that the antireflection layer has a limit voltage of less than 10 volts, across a layer thickness of the antireflection layer.

12. A test method for testing a solar cell comprising a front-side antireflection layer for its susceptibility to potential-induced degradation in a solar module, wherein, after applying the antireflection layer to a front-side surface of a semiconductor substrate of the solar cell, a corona discharge is produced on the antireflection layer, subsequently after the corona discharge an electrical surface voltage of the antireflection layer is measured and the solar cell is declared to be susceptible to potential-induced degradation if the measured electrical surface voltage is higher than a limit voltage of 10 volts.

13. The solar cell of claim 1, wherein said antireflection layer has a limit voltage of less than 5 volts across a layer thickness of the antireflection layer.

14. The solar cell of claim 1, wherein said antireflection layer has a limit voltage of less than 3 volts across a layer thickness of the antireflection layer.

15. The method of claim 11 wherein the antireflection layer has a limit voltage of less than 5 volts across a layer thickness of the antireflection layer.

16. The method of claim 11 wherein the antireflection layer has a limit voltage of less than 3 volts, across a layer thickness of the antireflection layer.

17. The solar cell according to claim 2, wherein the antireflection layer is doped.

18. The solar cell according to claim 2, wherein a transparent conductive oxide is admixed in the antireflection layer.

19. The solar cell according to claim 3, wherein a transparent conductive oxide is admixed in the antireflection layer.

20. The solar cell according to claim 4, wherein a transparent conductive oxide is admixed in the antireflection layer.
